(19) United States
(12) Patent Application Publication
(10) Pub. No.: US 2026/0024981 A1
(43) Pub. Date: Jan. 22, 2026

(54) System and Method for Quantifying Confidence Levels in Arc Fault Detection for Reliable Trip Decisions

(71) Applicant: ABB Schweiz AG, Baden (CH)

(72) Inventors: Edgar Albert Engel, Nussbaumen (CH); Christoph Winkelmann, Bern (CH); David Salido Monzu, Zürich (CH)

(73) Assignee: ABB Schweiz AG, Baden (CH)

(21) Appl. No.: 18/778,373

(22) Filed: Jul. 19, 2024

(51) Int. Cl. H02H 1/00; G01R 31/14; H02H 3/16

(52) U.S. Cl. CPC H02H 1/0015; G01R 31/14; H02H 1/0092; H02H 3/16

(57) ABSTRACT

A system for reliable tripping of an electrical circuit is provided. The system includes an electrical circuit, a circuit interrupter, and a controller. The circuit interrupter comprises one or more sensors configured to detect electrical signals associated with the electrical circuit and a switch to interrupt the circuit. The controller is configured to obtain, from the one or more sensors, a plurality of electrical signals associated with the electrical circuit. A circuit parameter is generated based on the plurality of electrical signals associated with the electrical circuit. Using an arc fault detection model, the circuit parameter is analyzed against given reference data to determine a statistical indicator of the presence or absence of an arc fault, where the reference data indicates healthy and faulty electrical circuits. The electrical circuit is tripped based on the statistical indicator.

### FIELD

The present disclosure relates to arc fault detection for circuit breakers for residential load centers. In particular, the present disclosure relates to arc fault circuit interrupters (AFCI) and dual function circuit interrupters (DFCI), which perform safety functionalities, including the detection of arc faults in series with masking loads.

### BACKGROUND

Arc fault detection in an electrical circuit is commonly based on current measurements. However, detecting arc faults with certainty is not possible because the behavior of the electrical circuit (e.g., the loads) is irregular and the behavior of arc faults in the electrical circuit is stochastic. Existing arc fault circuit detectors disregard the resultant probabilistic problem associated with detecting arc faults in a circuit. Existing arc fault circuit detectors, that are part of arc fault circuit interrupters, determine the presence of an arc fault and make decisions to trip a circuit based on heuristic criteria without quantifying a confidence level associated with determining the presence of the arc fault. This makes it difficult to compare and standardize different methods of arc fault detection.

### SUMMARY

A first aspect of the present disclosure provides a system for reliable tripping of an electrical circuit, the system comprising: an electrical circuit; a circuit interrupter, wherein the circuit interrupter comprises: one or more sensors configured to detect electrical signals associated with the electrical circuit; a switch to interrupt the circuit; and a controller configured to: obtain, from the one or more sensors, a plurality of electrical signals associated with the electrical circuit; generate a circuit parameter based on the plurality of electrical signals associated with the electrical circuit; analyzing, using an arc fault detection model, the circuit parameter and reference data to determine a statistical indicator of the presence or absence of an arc fault, wherein the reference data indicates healthy and faulty electrical circuits; and trip the electrical circuit, based on the determined statistical indicator.

According to an implementation of the first aspect, the determined statistical indicator determines whether an absence of an arc fault within the electrical circuit is rejected with a predefined confidence threshold.

According to an implementation of the first aspect, the statistical indicator computed by the arc fault detection model is a likelihood function.

According to an implementation of the first aspect, the plurality of electrical signals comprises a current signal and a voltage signal.

According to an implementation of the first aspect, the controller configured to generate the circuit parameter, is further configured to: filter the current signal into a high frequency portion and a low frequency portion; and determine a level of noise in the high frequency portion of the current signal.

A second aspect of the present disclosure provides a method for reliable tripping of an electrical circuit, the method comprising: obtaining, by a controller from one or more sensors configured to detect electrical signals, a plurality of electrical signals associated with the electrical circuit; generating, by the controller, a circuit parameter based on the plurality of electrical signals associated with the electrical circuit; analyzing, by the controller and an arc fault detection model, a comparison between the circuit parameter and reference data to determine a statistical indicator of the presence or absence of an arc fault, wherein the reference data indicates healthy and faulty electrical circuits; and tripping, by the controller and a switch, the electrical circuit, based on the determined indicator value.

According to an implementation of the second aspect, the inference determines whether an absence of an arc fault within the electrical circuit is rejected with a predefined confidence threshold.

According to an implementation of the second aspect, the statistical indicator computed by the arc fault detection model is a likelihood function.

According to an implementation of the second aspect, the plurality of electrical signals comprises a current signal and a voltage signal.

According to an implementation of the second aspect, generating the circuit parameter further comprises filtering the current signal into a high frequency portion and a low frequency portion; and determining a level of noise in the high frequency portion of the current signal.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a simplified diagram for a circuit interrupter system, according to one or more examples of the present disclosure;

FIG. 2 illustrates an exemplary circuit diagram related to a circuit interrupter system, according to one or more examples of the present disclosure;

FIG. 3 illustrates a workflow for a development and field application for an exemplary circuit interrupter system, according to one or more examples of the present disclosure;

FIG. 4 illustrates a graph of peak log-likelihood ratios observed for arcing and non-arcing reference data, according to one or more examples of the present disclosure;

FIG. 5 illustrates a simplified block diagram of one or more devices or systems within the exemplary environment of FIG. 1, according to one or more examples of the present disclosure; and

FIG. 6 illustrates a process performed by a controller as part of a circuit interrupter system, according to one or more examples of the present disclosure.

### DETAILED DESCRIPTION

Examples of the presented application will now be described more fully hereinafter with reference to the accompanying FIGS., in which some, but not all, examples of the application are shown. Indeed, the application may be exemplified in different forms and should not be construed as limited to the examples set forth herein; rather, these examples are provided so that the application will satisfy applicable legal requirements. Where possible, any terms expressed in the singular form herein are meant to also include the plural form and vice versa, unless explicitly stated otherwise. Also, as used herein, the term “a” and/or “an” shall mean “one or more” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.”

Arc fault detection in an electrical circuit cannot be performed with absolute certainty because the behavior of the electrical circuit and loads of the electrical circuit is irregular and the behavior of arc faults is stochastic in nature. Existing arc fault detectors used to detect the presence of an arc fault in the electrical circuit disregard the resultant probabilistic problem. Circuit interrupters (e.g., arc fault circuit interrupters and/or dual fault circuit interrupters) associated with the arc fault detectors make decisions to trip a circuit breaker of the electrical circuit based on heuristic criteria without quantifying the confidence associated with the detection of the arc fault.

The present disclosure describes a method to quantify a confidence with which a decision to trip an electrical circuit can be made. This facilitates (i) quantitative comparisons of different circuit designs during development and a meaningful assessment of the tradeoff between designs, (ii) distinguishing systematic tripping of electrical circuits due to problematic loads (e.g., nuisance tripping) from the occasional, sporadic unwarranted trip decision, (iii) establishing reliability requirements for internal guidelines or certifications, and (iv) identifying faulty equipment. Identifying faulty equipment also enables establishing clear procedures for repair, replacement and/or recall.

According to an embodiment of the present disclosure, the decision to trip the electrical circuit by a circuit interrupter (e.g., arc fault circuit interrupter and/or dual fault circuit interrupter) is formulated as a hypothesis test. A null hypothesis is that no arc fault is present in the electrical circuit. The electrical circuit is tripped by the circuit interrupter if the hypothesis (that no arc fault is present in the electrical circuit) can be rejected with a predefined level of confidence. The hypothesis is tested based on the usual indicative quantities that are observed on a per-half-cycle basis. For example, the amount of high-frequency noise power contained in the current flowing through the electrical circuit may be an indication of the presence of an arc fault present in electrical circuit. In some cases, the temporal characteristics of high-frequency noise power may also be used as an indication of the presence of an arc fault in the electrical circuit.

The observed values of the usual indicative quantities (e.g., the amount of high frequency noise present in the electrical circuit), may be used to compute a likelihood that the observed values are consistent with the hypothesis, of no arc fault being present in the electrical circuit. Computing the likelihood based on the observed values of indicative quantities requires an understanding of the conditional probabilities of measuring different values in the presence and absence of an arc fault in an electrical circuit, respectively. In practice the probabilities may be established in agnostic, data-driven fashion based on laboratory and field measurements with and without arc faults and including diverse masking loads.

When it is determined that the null hypothesis, of no arc fault being present in the electrical circuit, may be rejected with a confidence value above a certain threshold, the circuit interrupter trips the electrical circuit by a switch. In some embodiments, the certain threshold may be determined by a user associated with the electrical circuit based on analyzing the electrical circuit, load, and related parameters. For example, the certain threshold may be uniquely defined by a chosen number of half-cycles accounted for and a given preselected confidence value. In some examples, a user may determine the certain threshold by choosing to observe different numbers of half-cycles and requiring a particular level of confidence for tripping depending on where the device is applied.

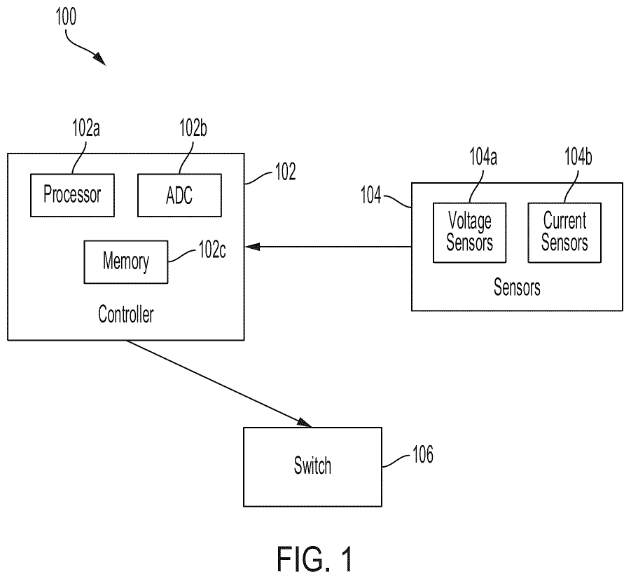

FIG. 1 illustrates a simplified diagram for a circuit interrupter system, according to one or more examples of the present disclosure. FIG. 1 includes a circuit interrupter system 100 that includes a controller 102, sensors 104, and a switch 106. Sensors 104 include voltage sensors 104a and current sensors 104b that detect current and voltage signals of an electrical circuit, while the electrical circuit is in operation. In some embodiments, the sensors 104 may include sensors apart from voltage sensors 104a and current sensors 104b that detect other signals of the electrical circuit. The sensors 104 provide the detected signals of the electrical circuit to the controller 102. The controller 102 includes a processor 102a, an analog-to-digital convertor (ADC) 102b and a memory 102c. The controller 102 receives the detected signals from the sensors 104 and processes the detected signals to compute circuit features. The computed circuit features are then used by the controller 102 to determine the conditional probabilities required to test (and reject or not) the hypothesis that no arc fault is present the electrical circuit. In case the determined likelihood is above a predetermined threshold, the controller 102 instructs a switch 106 to open, and interrupt the circuit.

In some embodiments, the circuit features are computed based on a series of processes performed on the detected signals received by the controller 102 from the sensors 104. For example, the signals received from the sensors 104 may be filtered by the processor 102a of the controller 102. The current signal from the various signals may be separated into a low frequency part and a high frequency part and the different parts may be analyzed separately. In some embodiments, the high frequency part of the current signal may be converted from an analog signal to a digital signal using ADC 102b. The digital form of the high frequency part of the current signal of the electrical circuit may be used to compute circuit features that are indicative of an arc fault present in the circuit. For example, the high frequency part may further be analyzed to determine a level of noise present. The level of noise present in the high frequency part of the current signal from the electrical circuit may be indicative of the presence of an arc fault in the electrical circuit. In some examples, the circuit features may be determined by combining values associated with various signals of the electrical circuit in a way to attain a single computed circuit feature value that may be an indicator that an arc fault is present in the electric circuit.

In some embodiments, a principal component analysis may be used to select and combine various signals of the electrical circuit to generate the circuit feature. In some other embodiments, other methods for selecting and combining signals may be used.

In some embodiments, statistical analysis may be performed on the computed circuit feature (e.g., the high frequency part of the current signal) to derive a statistical indicator of the presence or absence of an arc fault. The statistical indicator may then be used to test the null hypothesis (e.g., that an arc fault is not present in the electrical circuit). In some cases, the level of noise that is computed from the high frequency part of the current signal of the electrical circuit may be compared to reference data (e.g., data associated with healthy and faulty circuits) to determine a confidence value associated with the presence of an arc fault within the electrical circuit based on the level of noise.

The processor 102 compares the confidence value to a preset threshold. In some embodiments, the preset threshold may reflect a statistical analysis of how frequent arc faults are in load centers and the relative costs of nuisance trips versus failures to detect arc faults.

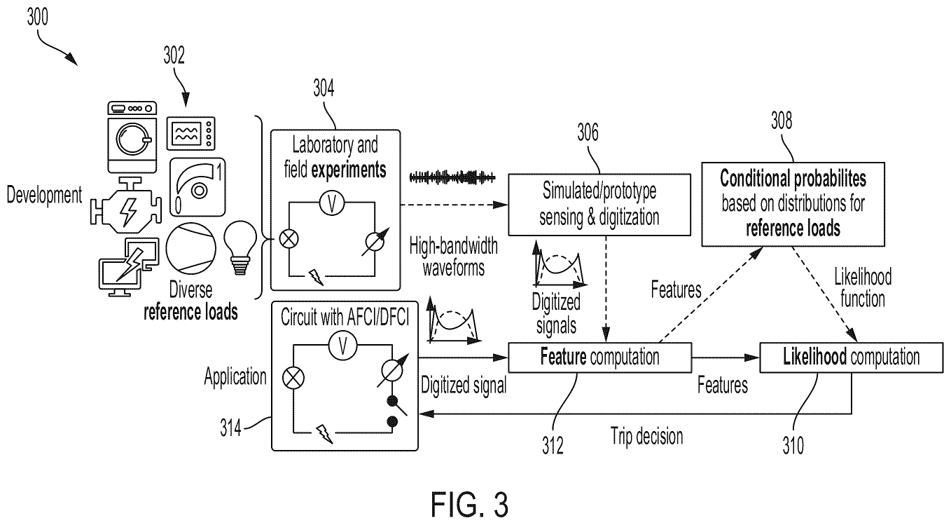

In case the processor 102 determines that the confidence value is greater than the present threshold, the processor 102 instructs the switch 106 to open an interrupt the electric circuit. The computation of circuit features and the likelihood function are described in more detail with respect to FIG. 3.

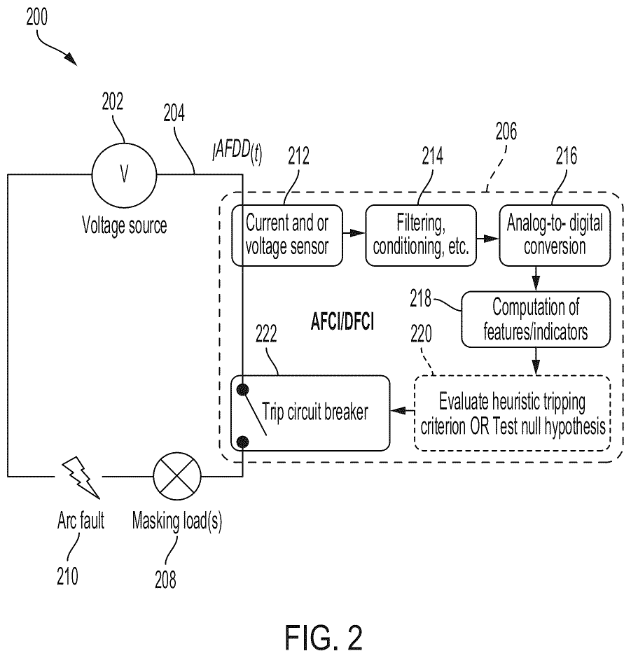

FIG. 2 illustrates an exemplary circuit diagram related to a circuit interrupter system, according to one or more examples of the present disclosure. Circuit diagram 200 of FIG. 2 depicts an electrical circuit. The electrical circuit, depicted by way of a circuit diagram 200, of FIG. 2 includes a voltage source 202 to power the circuit, a masking load 208, and a circuit interrupter 206 all connected in series. A current 204 may be flowing through the electrical circuit until a switch 220 of the circuit interrupter 206 is set to open to break the electrical circuit. The circuit interrupter 206 may instruct the switch 222 to open to break the circuit based on whether an arc fault 210 is detected in the circuit.

The circuit interrupter 206 is similar to the circuit interrupter system 100 as depicted in FIG. 1. Current and voltage sensors 212 of the circuit interrupter 206 are similar to the voltage sensor 104a and the current sensor 104b of the sensors 104 of the circuit interrupter 100 as shown in FIG. 1. The current and voltage sensors 212 may detect signals current and voltage signals from the electrical circuit. The current and voltage signals are provided to a controller to be processed. Blocks 214, 216, 218, 220 depict processes that are performed on the current and voltage signals provided by the current and voltage sensors to determine a confidence level at which the null hypothesis, of an arc fault not present in the electrical circuit, may be refuted. The steps laid out in blocks 214, 216, 218, and 220, may be performed by the controller 102 of the circuit interrupter system 100 shown in FIG. 1. For example, the processor 102a of the controller 102 of the circuit interrupter system 100 may be used to filter the current and voltage signals received from the current and voltage sensors 212. The filtered signals may then be converted to digital signals at 216 by the ADC 102b of the controller 102 of the circuit interrupter system 100 shown in FIG. 1. The processor 102a of the controller 102 may use the digital filtered signals to compute circuit features that are indicative of whether an arc fault 220 is present in the electrical circuit. The processor 102a of the controller 102 may perform statistical analysis on the computed circuit features to derive a statistical indicator of the presence or absence of an arc fault. The statistical indicator is used to test the null hypothesis. As discussed above, the null hypothesis is the hypothesis that there is no arc fault present in the electrical circuit. At 220, the processor 102a of the controller 102 may determine a confidence level that the null hypothesis may be refuted. The confidence level may be computed given the statistical likelihood that an arc fault is present determined using a likelihood function stored in memory 102c.

The processor 102a may determine whether the confidence value is greater than a predetermined threshold. The predetermined threshold may be set based on characteristics associated with the electrical circuit. Based on determining that the confidence value is above a predetermined threshold, the controller 102 may instruct the switch 222 to set to open to interrupt the circuit. The switch 222 is similar to switch 106 of the circuit interrupter system 100 of FIG. 1.

FIG. 3 illustrates a workflow for a development and field application for an exemplary circuit interrupter system, according to one or more examples of the present disclosure. Element 302 of FIG. 3 depicts a plurality of masking loads that may be used as the masking load 208 that is shown as part of the circuit depicted by circuit diagram 200 of FIG. 2. In some embodiments, a minimal masking load set is defined by the Underwriters Laboratories (UL) standards. According to some examples, masking loads may include common household appliances like television sets or laundry machines. An experimental setup 304 is used to understand characteristics of an electrical circuit during operation of the electrical circuit. In some embodiments, the experimental setup may include a circuit similar to the electrical circuit depicted by circuit diagram 200 in FIG. 2. In some embodiments, experiments are performed as part of the experimental setup 304 by varying a plurality of parameters of the electrical circuits and using a variety of masking loads in the electrical circuit. For example, the experimental setup 304 may be used to acquire reference data/signals corresponding to healthy and faulty circuits operating in a variety of different conditions. From each experiment, various measurements associated with the experiment (e.g., reference data) may be extracted. In some embodiments, the measurements may be extracted in the form of electrical signals. The process of extraction and filtering the signals from an electrical circuit is described in more detail with respect to FIGS. 1 and 2.

At 306, the signals are converted to digital signals using an analog-to-digital convertor, similar to the ADC converter 102c of the circuit interrupter system 100 described in FIG. 1. The digitized signals are then used to compute circuit features at 312. The computation of circuit features is described in more detail with respect to FIGS. 1 and 2. The computed circuit features are then provided to block 308 where conditional probabilities of the presence of an arc fault within an electrical circuit, based on the computed circuit features, are determined. In some embodiments, the knowledge of whether an arc fault exits in the electrical circuit from the plurality of testing conditions at the experimental setup 304, along with the computed electrical features of each of the plurality of testing conditions from the experimental setup 304 that are computed at 312, may be combined to determine conditional probabilities of the presence of an arc fault in any electrical circuit. The conditional probabilities may be computed by observing the computed electrical features conditioned on the presence and absence of an arc fault.

In some embodiments, in order to obtain the conditional probabilities, the electrical measurements obtained from the various simulations of the experimental setup 304 may be used to determine the difference in statistical distributions of electrical measurements for healthy circuits (e.g., when no arc fault present) and faulty circuits (e.g., when an arc fault is present). The statistical distributions of measurements for healthy and faulty, define the empirical probabilities of obtaining a particular set of electrical measurements (or downstream circuit features) if an arc fault is present and absent, respectively. The empirical probabilities are strictly defined from the reference electrical measurements, and are not unambiguous.

In some embodiments, the probability of obtaining a particular set of measurements is proportional to the frequency of observations in the reference experiments. The distributions of measurements describe frequencies with which different sets of measurements were observed. For example, the probability of obtaining a particular set of measurements is proportional to the value of the distribution at the particular measurement values.

For example, as described above, noise in a high frequency portion of the current signal of an electrical circuit suggests the presence of an arc fault within an electrical circuit. Generally, the higher the noise detected in the signal, the higher the probability of an arc fault in the circuit. Based on this analysis, the noise in a high frequency portion of a current signal of the electrical circuit may be selected as a circuit feature, and based on the value of the computation feature, a conditional probability of an arc fault being present in the electrical circuit may be computed.

At block 310 the empirical probabilities may be used in a plurality of different statistical hypothesis testing frameworks. In some embodiments, the hypothesis testing framework may be a likelihood ratio test. The log-likelihood ratio is defined as the logarithm of the product of the ratios of conditional probabilities computed for (consecutive) half-cycles. A threshold value for the log-likelihood ratio corresponding to a given confidence level can be computed using the properties of the so-called chi-squared distribution for the chosen number of half-cycles.

The hypothesis in this case is that there is no arc fault present in the electrical circuit. The term likelihood may refer to the mathematical likelihood function, which may be equal to the empirical probabilities of obtaining a particular set of measurements if an arc fault is present and absent, respectively. The ratio in the likelihood ratio test refers to the ratio of probabilities given the presence and absence of an arc fault, respectively. In the likelihood ratio test the product of the ratios computed for measurements for multiple half-cycles are compared to a threshold value, which is fixed once the required confidence in the final trip decision has been defined.

In some embodiments, the manufacturer, a standards body such as Underwriters Laboratories (UL), or a user may decide that a minimum confidence level such as 99% should be required before a circuit is tripped to avoid costly circuit downtime or maintenance activities (given that arc faults occur rarely). They may then set the required confidence to be 99%. This choice of value for the confidence level is then translated into a threshold value for the log likelihood ratio through a (in the mathematic/statistical community) well established mathematic relation, which is based on the properties of the above referenced chi-squared distribution.

For example, the conditional probabilities may be used to determine the ratio of likelihoods for a given half-cycle at a likelihood computation block 310.

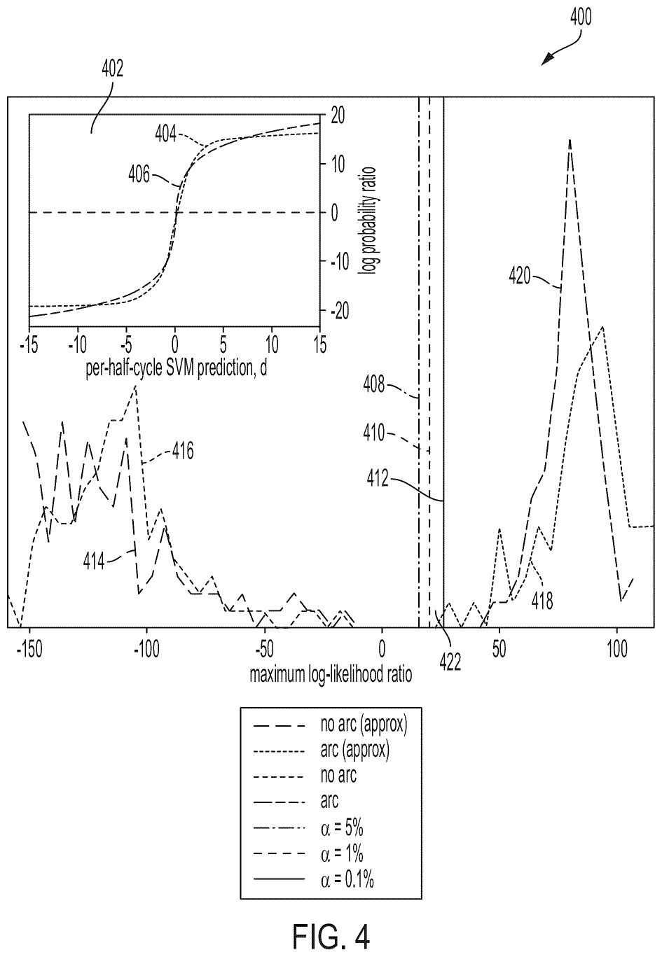

In some embodiments, according to a different statistical hypothesis testing framework the distribution of measurements for healthy and faulty circuits as described above may be sampled in order to establish a likelihood ratio function, which is then used to compute likelihood ratios based on measurements for a circuit of unknown status in order to determine whether an arc fault is present with sufficient certainty to trip the breaker. (e.g.-requiring anywhere between 95 to 99.9% confidence in the presence of an arc fault for tripping the breaker). This is discussed in greater detail with respect to FIG. 4. For example, the likelihood ratio test may be used to translate the computed likelihood ratio for one or (more typically) multiple half-cycles into a rejection (or not) of the null-hypothesis, e.g., into a trip decision.

In some embodiments, the ratio of likelihood established in agnostic, data-driven fashion based on laboratory and/or field data for both arcing and non-arcing circuits including diverse, representative masking loads.

Once the likelihood function is determined, at 310, the likelihood function is applied to electrical circuits. An exemplary electrical circuit 314 is similar to the electrical circuit shown in the circuit diagram 200 of FIG. 2. The exemplary electrical circuit 314 includes an arc fault circuit interrupter (AFCI) 206 as shown in FIG. 2. Signals from the electrical circuit 314 are processed to generate digitized signals that are provided to 312 for computation of circuit features. The computed circuit features are provided to the likelihood function at 310 to determine a likelihood that an arc fault is present in the electrical circuit 314. In some embodiments, in order to determine the likelihood, statistical inference is performed on the circuit features. For example, the circuit features are compared with the reference data that indicate arcing and non-arcing conditions. The comparison between the reference data and the circuit features may be used to perform statistical analysis. The statistical analysis on the comparison may determine a likelihood that an arc fault is present in a circuit. Based on determining the likelihood of the presence of the arc fault is greater than a threshold value determined by the preset/required confidence level, the hypothesis, of the arc fault not being present in the electrical circuit, may be rejected and the arc fault circuit interrupter may trip the electrical circuit. The decision of whether to trip the electrical circuit 314, is communicated to the electrical circuit 314.

FIG. 4 illustrates a graph of peak log-likelihood ratios observed for arcing and non-arcing reference data, according to one or more examples of the present disclosure.

Graph 400 of FIG. 4 depicts distributions of two log-likelihood ratios for arcing and non-arcing reference data. Graph 402 within the graph 400 shows two different log-likelihood functions 404 and 406. In some embodiments, the different log-likelihood functions 404 and 406 may be generated using the same set of data from the experimental setup 304. For example, the distribution of values of noise in a high frequency portion of a current signal of the electrical circuit for a plurality of arcing and non-arcing conditions, may be sampled and fit to generate two different log-likelihood functions 404 and 406. In some embodiments, the log-likelihood functions 404 and 406 may be generated using different computed electrical features of an electrical circuit, or varying combination of different features.

Curves 414 and 416 plot reference data for a distribution of peak log-likelihood ratios in non-arcing conditions. Curve 414 corresponds to the log-likelihood function 404 and curve 416 corresponds to the log-likelihood function 406.

Curves 418 and 420 plot reference data for a distribution of peak log-likelihood ratios in non-arcing conditions. Curve 418 corresponds to the log-likelihood function 404 and curve 420 corresponds to the log-likelihood function 406.

Curves 408, 410, and 412 are the confidence thresholds for tripping with 95, 99, and 99.9% confidence. When the confidence threshold for tripping is set at 95%, the log-likelihood function should be able to refute the null hypothesis that there is no arc fault present in an electric circuit with a confidence level of 95%. As is seen from the graph 402, when the confidence tripping threshold is set at 95%, shown by curve 408, the log-likelihood functions 404 and 406 are able to correctly predict the presence of an arc fault in an electric circuit. This is evident from the fact that the curves 416 and 418, that are plots of reference data in non-arcing conditions fall to the left of the curve 408, and the curves 418 and 420, that are plots of reference data in arcing conditions fall to the right of the curve 408. Similarly, when the confidence tripping threshold is raised to 99%, shown by curve 410, the log-likelihood functions 404 and 406 are also able to correctly predict the presence of an arc fault in the electric circuit, as seen in graph 400 of FIG. 4. Thus, the log-likelihood functions 404 and 406 can accurately predict the occurrence of an arc fault within an electric circuit with a confidence of 95% or 99%.

In cases when the confidence tripping threshold is set at 99.9%, as shown by curve 99.9%, a certain portion 422 of the curve 418 falls to the right of the curve 418. This means that the log-likelihood function 404, cannot predict the occurrence of the arc fault in the electric circuit with a confidence of 99.9% in those conditions. On the other hand, as curve 420 falls completely to the right of the curve 420, the log-likelihood function 406 can accurately predict the occurrence of an arc fault within an electric circuit with a confidence of 99.9%. The various plots of confidence levels helps in setting up a confidence threshold and/or level at which an arc fault detector should instruct a switch to break a circuit.

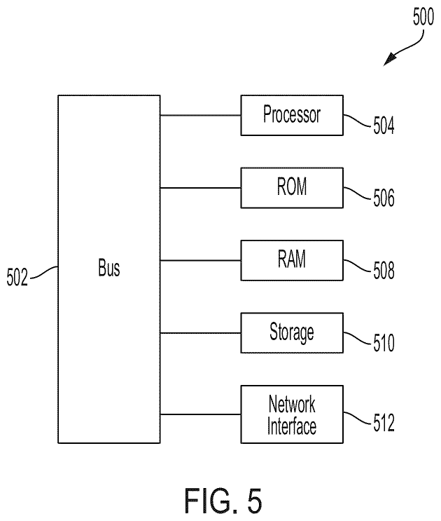

FIG. 5 is a block diagram of an exemplary system or device 500 within the circuit interrupter system 100. The system 500 has a central processing unit (CPU), and/or logic, that executes computer executable instructions for performing the functions, processes, and/or methods described herein. In some examples, the computer executable instructions are locally stored and accessed from a non-transitory computer readable medium, such as storage 510, which may be a hard drive or flash drive. Read Only Memory (ROM) 506 includes computer executable instructions for initializing the processor 504, while the random-access memory (RAM) 508 is the main memory for loading and processing instructions executed by the processor 504. The network interface 512 may connect to a wired network or cellular network and to a local area network or wide area network. The system 500 may also include a bus 502 that connects the processor 504, ROM 506, RAM 508, storage 510, and/or the network interface 512. The components within the system 500 may use the bus 502 to communicate with each other. The components within the system 500 are merely exemplary and might not be inclusive of every component within the components of the bin picking system 100, such as controller 102. Additionally, and/or alternatively, the system 500 may further include components that might not be included within every entity of system 500. For instance, in some examples, the controller 102 might not include a network interface 512.

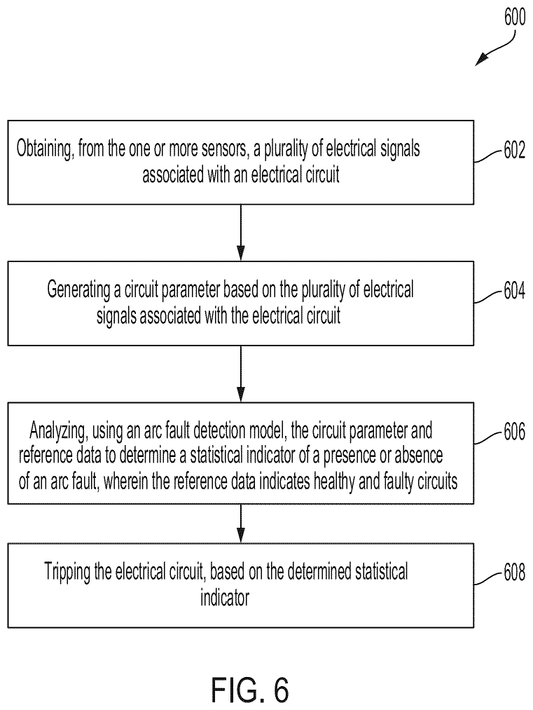

FIG. 6 illustrates a process performed by a controller as part of the circuit interrupter system, according to one or more examples of the present disclosure. However, it will be recognized that any of the following blocks may be performed in any suitable order and that the process 600 may be performed in any environment and by any suitable computing device and/or controller.

At 602, the controller 102 obtains from the one or more sensors, a plurality of electrical signals associated with an electrical circuit. For example, the controller 102 may receive signals detected by sensors 104 that are part of an electrical circuit. The sensors 104 may include a voltage sensor 104a and a current sensor 104b. As shown with respect to FIG. 3, signals from an exemplary circuit 314 may be retrieved using a plurality of sensors (e.g., voltage sensors and current sensors).

At 604, the controller 102 generates a circuit parameter based on the plurality of electrical signals associated with the electrical circuit. For example, the circuit parameter may be generated by processing the signals received from the sensors 104. The processor 102a of the controller 102 may filter a current signal from an electrical circuit to high frequency and low frequency parts. The high frequency part of the current signal may be digitized using ADC 102b and used to compute a circuit parameter (e.g., level of noise in the high frequency part of the current signal). The processing of signals to determine a circuit parameter (e.g., circuit feature) is also described in more detail with respect to blocks 306 and 312 of the development process described in FIG. 3.

At 606, the controller 102 analyzes, using an arc fault detection model, a relation between the circuit parameter and reference data to determine a statistical indicator of the presence or absence of an arc fault, wherein the reference data indicates healthy and faulty electrical circuits. For example, the arc fault detection model may comprise a log-likelihood function or a likelihood ratio that is generated based on a distribution of circuit reference values obtained from an experimental setup of an electrical circuit in a plurality of operating conditions, including arcing and non-arcing conditions. The computed circuit parameter may be compared with the distribution of reference data for arcing and non-arcing conditions. A confidence value associated with the computed circuit parameter that an arc fault is present in the electrical circuit may be determined based on the statistical comparison. The generation of the log-likelihood function or log-likelihood ratio is described in more detail with respect to blocks 308 and 310 of FIG. 3. As described in FIG. 3, the log-likelihood function or log-likelihood ratio is determined by creating a distribution of measurements (e.g., reference data) of healthy and faulty circuits obtained from experiments 304 with a plurality of operating conditions. The reference data may be a circuit feature (e.g., a level of noise in a high frequency portion of an electrical signal of an electrical circuit) that is computed as described with respect to block 312 of FIG. 3. At block 308 of FIG. 3, the statistical distributions of measurements (e.g., reference data) for healthy and faulty, define the empirical probabilities of obtaining a particular set of electrical measurements if an arc fault is present and absent, respectively. At block 310, the empirical probabilities may be used in a plurality of different statistical hypothesis testing frameworks, such as a log-likelihood function or a log-likelihood ratio.

Once the arc detection model (e.g., log-likelihood function or log-likelihood ratio) is generated, FIG. 3 also describes how the measurements (e.g., circuit parameters) obtained from an electrical circuit may be used to determine the presence of an arc fault within the circuit. For example, as described with respect to blocks 602 and 604, signals received from an exemplary circuit 314 are processed to determine circuit features (e.g., a level of noise in a high frequency portion of an electrical signal of an electrical circuit). The computed circuit features are provided to the arc fault detection model to determine whether an arc fault is present. In making the determination, the computed circuit parameter may be compared with the distribution of reference data for arcing and non-arcing conditions.

At 608, the controller trips the electrical circuit, based on the determined statistical indicator of the presence or absence of an arc fault. For example, in case the confidence value associated with the computed circuit parameter is determined to be greater than a preset confidence threshold, the controller 102 may instruct a switch 106 to trip the electrical circuit. As shown in FIG. 3, the decision to trip the circuit, made using the arc detection model (e.g., a log-likelihood function or a log-likelihood ratio), may be based on a confidence value that the null hypothesis of no arc fault being present in the circuit can be rejected. In case the confidence value is greater than a preset threshold, a decision is made to trip the electrical circuit. Else, the decision is made to not trip the circuit. The decision may be communicated to the circuit 314 of FIG. 3.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A system for reliable tripping of an electrical circuit, the system comprising:
an electrical circuit;
a circuit interrupter, wherein the circuit interrupter comprises:
one or more sensors configured to detect electrical signals associated with the electrical circuit;
a switch to interrupt the circuit; and
a controller configured to:
obtain, from the one or more sensors, a plurality of electrical signals associated with the electrical circuit;
generate a circuit parameter based on the plurality of electrical signals associated with the electrical circuit;
analyzing, using an arc fault detection model, the circuit parameter and reference data to determine a statistical indicator of a presence or absence of an arc fault, wherein the reference data indicates healthy and faulty electrical circuits; and
trip the electrical circuit, based on the determined statistical indicator.

2. The system of claim 1, wherein the determined statistical indicator determines whether an absence of an arc fault within the electrical circuit is rejected with a predefined confidence threshold.

3. The system of claim 1, wherein statistical indicator computed by the arc fault detection model is a likelihood function.

4. The system of claim 1, wherein the plurality of electrical signals comprise a current signal and a voltage signal.

5. The system of claim 4, wherein the controller configured to generate the circuit parameter, is further configured to:
filter the current signal into a high frequency portion and a low frequency portion; and
determine a level of noise in the high frequency portion of the current signal.

6. A method for reliable tripping of an electrical circuit, the method comprising:
obtaining, by a controller from one or more sensors configured to detect electrical signals, a plurality of electrical signals associated with the electrical circuit;
generating, by the controller, a circuit parameter based on the plurality of electrical signals associated with the electrical circuit;
analyzing, by the controller and an arc fault detection model, a comparison between the circuit parameter and reference data to determine a statistical indicator of the presence or absence of an arc fault, wherein the reference data indicates healthy and faulty electrical circuits; and
tripping, by the controller and a switch, the electrical circuit, based on the determined statistical indicator.

7. The method of claim 6, wherein the inference determines whether an absence of an arc fault within the electrical circuit is rejected with a predefined confidence threshold.

8. The method of claim 6, wherein the statistical indicator computed by the arc fault detection model is a likelihood function.

9. The method of claim 6, wherein the plurality of electrical signals comprises a current signal and a voltage signal.

10. The method of claim 9, wherein generating the circuit parameter further comprises:
filtering the current signal into a high frequency portion and a low frequency portion; and
determining a level of noise in the high frequency portion of the current signal.
